(19) United States
(12) Patent Application Publication
(10) Pub. No.: US 2009/0322321 A1
(43) Pub. Date: Dec. 31, 2009

(54) Magnetic roof impact sensor

(75) Inventor: Markus J. Schiefele, Novi, MI (US)

Correspondence Address: FOLEY AND LARDNER LLP;SUITE 500, 3000 K STREET NW, WASHINGTON, DC, 20007, US

(73) Assignee: TK Holdings Inc.

(21) Appl. No.: 12/213,996

(22) Filed: Jun. 27, 2008

(51) Int. Cl. B60R 16/02; G01R 33/02; G01N 27/72

(52) U.S. Cl. 324/228; 324/200; 340/436; 701/45

(57) ABSTRACT

A roof sensor for a vehicle is provided. A sensor is mounted in proximity to the roof of the vehicle for monitoring the deformation of the roof caused by impact during a crash, particularly when the vehicle rolls over. A vehicle safety system is also provided. A sensor, mounted in proximity to the roof of a vehicle, monitors the deformation of the roof. A controller is connected to the sensor, a safety device, and a vehicle communication device. Based on the severity of the deformation of the roof caused by an impact, the controller activates the safety device to prevent injury to vehicle passengers and communicates the status of the vehicle to a third party such as emergency services.

### BACKGROUND

The present invention generally relates to the field of vehicle safety. Roof impact during rollovers as a result of a vehicle accident are a significant source of injury for passengers in a vehicle. Roof airbags can be used to protect occupants in a roof impact scenario. In addition, post crash evaluation systems are used to send crash severity information to rescue personnel. A reliable and accurate system for detecting roof impact and evaluating the severity of roof impact is needed in order to control the above-mentioned safety systems in an efficient and effective manner.

### SUMMARY

A sensor system may include a coil having a square or rectangular-shaped cross-sectional winding pattern that may be used to generate an electromagnetic effect with an electrically conductive (e.g., metal) surface. Movement of the electrically conductive surface towards the coil or away from the coil causes a change in the electromagnetic effect resulting in a change in impedance and inductance of the surface and coil. A controller may be used to sense this change in impedance or inductance. In a vehicle, this sensed change (e.g., resulting from an accident causing the vehicle body to buckle, dent, or move) may prompt the actuation of a safety device such as an airbag. U.S. Patent Publication Nos. 20080068008, 20070024277, WIPO Publication No. WO2007114870, and U.S. Pat. Nos. 7,212,895, 7,209,844, and 6,587,048 describe various magnetic sensing systems and are incorporated by reference herein in their entirety. The sensor and systems disclosed herein may be used in conjunction with the systems disclosed in the aforementioned patent publications.

According to one embodiment, a roof sensor for a vehicle includes a sensor mounted in proximity to the roof of the vehicle, for monitoring the position of the roof.

According to another embodiment, a roof impact sensor includes a coil, mounted in proximity to the roof of the vehicle, for monitoring the position of the roof.

According to yet another embodiment, a vehicle safety system includes a sensor, mounted in proximity to the roof of a vehicle for monitoring the position of the roof, a controller operably connected to the sensor, a safety device connected to the controller and a vehicle communication device connected to the controller for communicating a status of the vehicle to a third party.

According to still another embodiment, a vehicle, includes a vehicle safety system, comprising a sensor mounted in proximity to the roof of a vehicle, for monitoring the position of the roof, a controller, operably connected to the sensor, a safety device, connected to the controller and a vehicle communication device, connected to the controller for communicating a status of the vehicle to a third party.

A method for determining the severity of a roof impact in a vehicle, comprising providing a roof sensor, detecting a change of position of the roof, determining whether to activate a safety device based on the change of position of the roof and calculating the severity of impact on the roof based on the change of position of the roof.

It is to be understood that both the foregoing general description and the following detailed description are exemplary and explanatory only, and are not restrictive of the invention as claimed.

### BRIEF DESCRIPTION OF THE DRAWINGS

FIG. 1 is a diagram of a vehicle with a roof sensor according to one embodiment, according to one embodiment.

FIG. 2 is a diagram of a roof sensor for a vehicle mounted to a reinforcement bar, according to one embodiment.

FIG. 3 is a diagram of a roof sensor for a vehicle mounted to a bracket, according to one embodiment.

FIG. 4 is a diagram of a roof sensor for a vehicle mounted to the roof, according to one embodiment.

FIG. 5 is a graph of the magnitude of the impedance of a roof sensor as it approaches sheet metal, according to one embodiment.

FIG. 6 is a graph of the phase of the impedance of a roof sensor as it approaches sheet metal, according to one embodiment.

FIG. 7 is a block diagram of a safety system according to one embodiment.

FIG. 8 is a flowchart illustrating an operation of the safety system shown in FIG. 7, according to one embodiment.

### DETAILED DESCRIPTION

Embodiments of the present invention will be described below with reference to the accompanying drawings. It should be understood that the following description is intended to describe exemplary embodiments of the invention, and not to limit the invention.

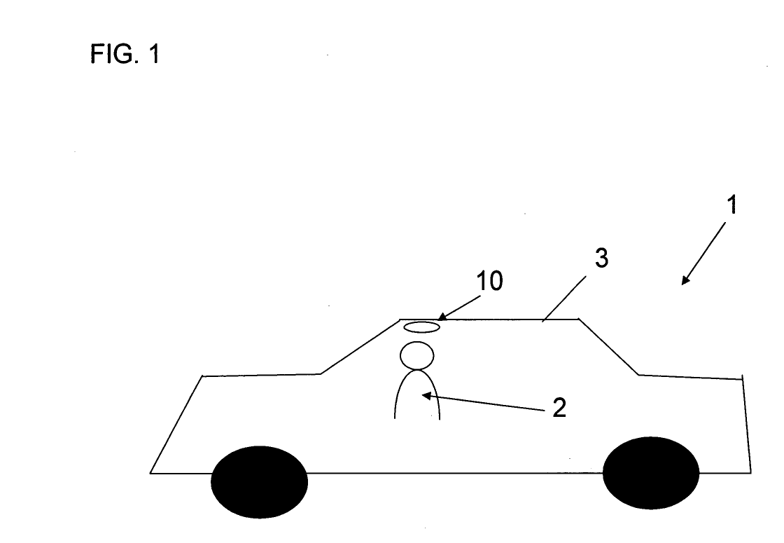

FIG. 1 is a diagram of a vehicle 1 with an occupant 2. A roof sensor 10 is mounted in proximity to the roof 3 of the vehicle 1 to monitor any change in position of the roof.

According to one embodiment, the roof sensor 10 is a coil. Preferably, the coil is a magnetic air core coil (air coil). According to another embodiment the sensor is implemented using any one of the systems described in U.S. Patent Publication Nos. 20080068008, 20070024277, WIPO Publication No. WO2007114870, and U.S. Pat. Nos. 7,212,895, 7,209,844, and 6,587,048 incorporated by reference herein in their entirety. Preferably the roof 3 or components of the roof 3 are electrically conductive so that the coil can be used to detect deformations in the roof 3. According to yet another embodiment, the sensor 10 can be any one of an accelerometer, pressure sensor, body sound sensor or magnetostrictive sensor.

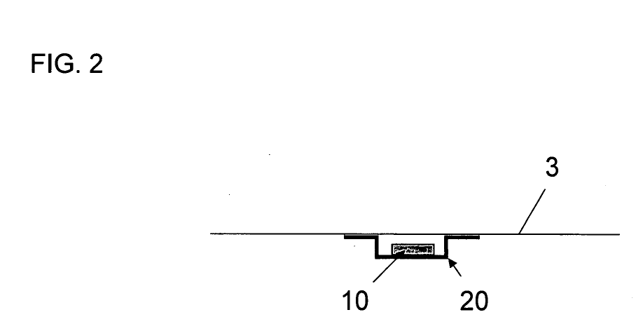

The sensor 10 can be placed in proximity to the roof 3 in various ways. For example, FIG. 2 shows a reinforcement member 20 mounted to the roof 3. According to one embodiment, the reinforcement member 20 is a u-shaped member having at least two attachment points that mount to the roof 3. An opening exists between the reinforcement member 20 and the roof 3. According to one embodiment, the sensor 10 is mounted to the reinforcement member 20. Preferably, as shown in FIG. 2, the sensor 10 is attached to the reinforcement member 20 so that it is positioned in the opening between the reinforcement member 20 and the roof 3. According to another embodiment, the sensor 10 may be mounted to the roof 3 so that it is positioned in the opening between the reinforcement member 20 and the roof 3. In both afore-mentioned configurations, the sensor 10 is enclosed by the reinforcement member 20.

In the configuration show in FIG. 2, the sensor 10 is very close to the electrically conductive roof 3 or reinforcement member 20. In an embodiment where the sensor 10 is a coil, the coil is very sensitive to fluctuations in the roof 3 or reinforcement member 20. Because a coil implementation of the embodiment shown in FIG. 2 is sensitive to localized fluctuation, the embodiment is also not as susceptible to misuse or false readings.

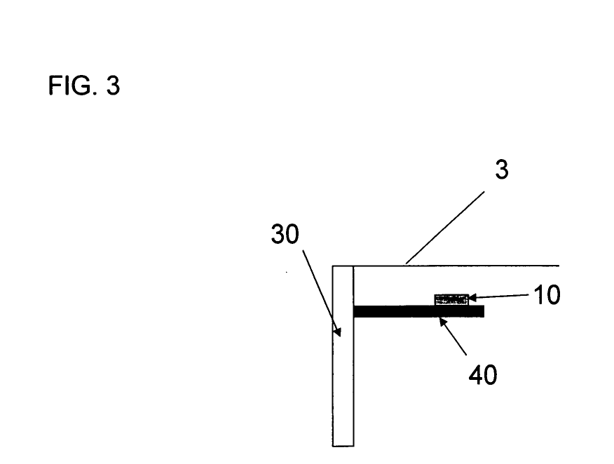

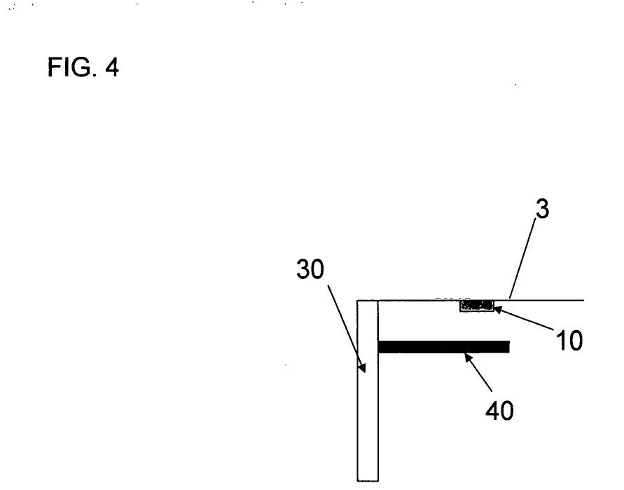

FIG. 3 depicts a pillar 30 of a vehicle. The pillar 30 may be any of an A, B or C vehicle pillar. A bracket 40 is mounted to the pillar 30 in proximity to the roof 3. Preferably, the bracket 40 or components of the bracket 40 are electrically conductive. A sensor 10 is mounted to the bracket 40. In the embodiment shown in FIG. 3, where the sensor 10 is a coil, the coil monitors the approach of the electrically conductive roof 3 toward or away from the bracket 40. The arrangement shown in FIG. 3 is adept at detecting broad deformations in the roof 3. In the alternative, as shown in FIG. 4, the sensor 10 can be mounted to the roof 3. In the embodiment shown in FIG. 4 where the sensor 10 is a coil, the coil moves with any deformation in the roof 3 and monitors the change in distance of the roof 3 to and from the electrically conductive bracket 40.

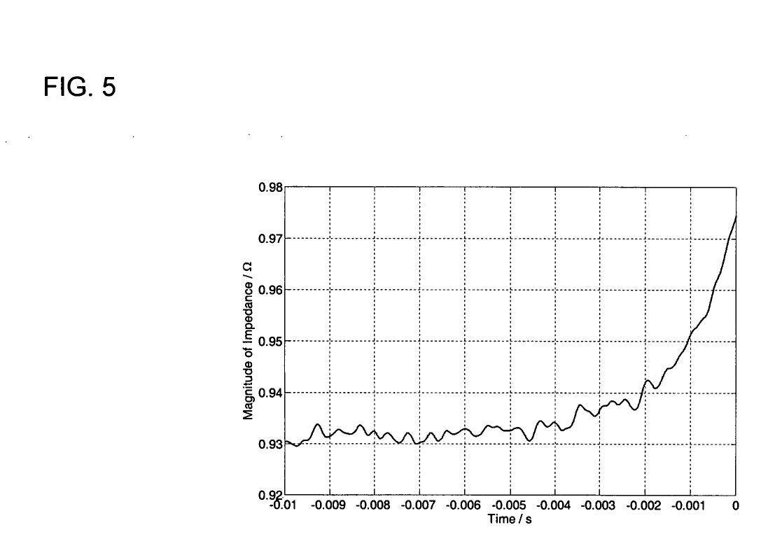

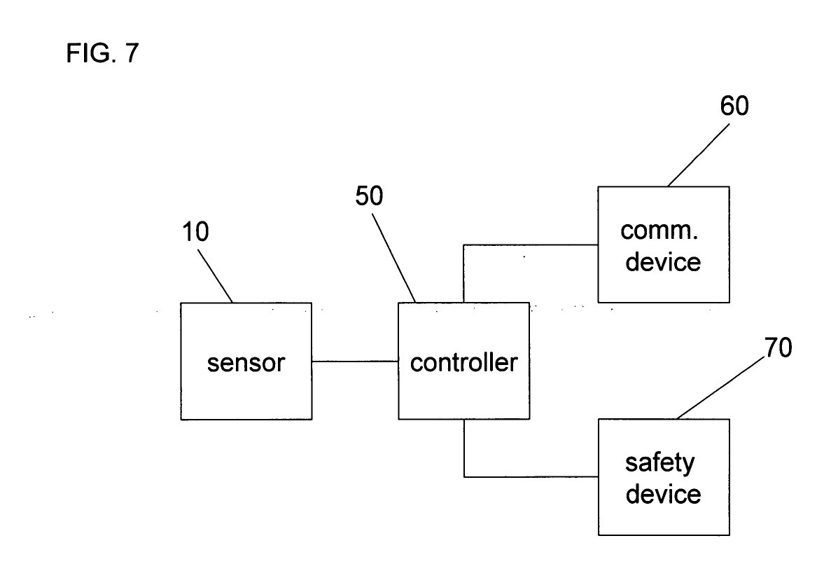

The operation of the sensor 10 and a vehicle safety system 100 using the sensor 10 (shown in FIG. 7) will now be described with reference to FIGS. 5-8.

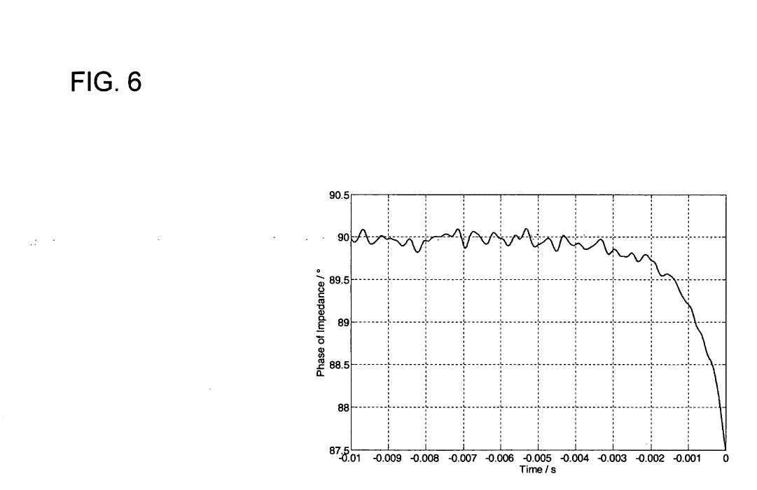

FIGS. 5 and 6 illustrate the performance of a coil as the sensor 10. A coil, such as an air core coil is capable of monitoring the position of electrically conductive material relative to the coils own position. The change in position of the electrically conductive material causes a change in the impedance of the coil. FIG. 5 shows that the magnitude of impedance of the coil increases as the coil approaches electrically conductive material (e.g., the roof sheet metal). In FIG. 5, the coil, mounted on a thruster, approaches the electrically conductive material with approximately 36.5 kph where the time 0 is the time of impact. FIG. 6 shows the measurement of the phase of impedance during the same experiment. As shown, the phase of impedance of the coil decreases as the coil approaches electrically conductive material. Thus, the impedance measurement over time can indicate whether there has been an impact on the electrically conductive material (e.g., roof) and if there has been an impact, indicate how severe the impact was.

FIG. 7 shows a block diagram of a vehicle safety system 100. The sensor 10 is operably connected to a controller 50 so that the sensor 10 can receive signals from the controller 50. According to another embodiment, the controller 50 and sensor 10 are integrated into a single component. According to one embodiment the controller 50 is a circuit or integrated circuit (e.g. microprocessor, CPU) configured to communicate with other vehicle components and manage the operation of the vehicle safety system 100. As shown in FIG. 7, the controller 50 is operably connected to a communication device 60 and a safety device 70. The communication device 60 can be any device for transmitting a signal. Preferably, the communication device 60 is a wireless transmitter that can transmit a signal to third party receivers. According to one embodiment, the communication device 60 is integrated with other vehicle systems such as the speedometer, gas gauge, GPS, etc., so that it can transmit other vital conditions/status of the vehicle 1. For example, the communication device 60 can be integrated with systems such as OnStar™ and AIDER™. The safety device 70 can be any device used to protect the passenger in a vehicle or prevent the vehicle from being damaged. For example, the safety device 70 can be an airbag (i.e., side, passenger, driver, roof, etc.) a seatbelt pretensioner for tightening seatbelts, alarms, etc.

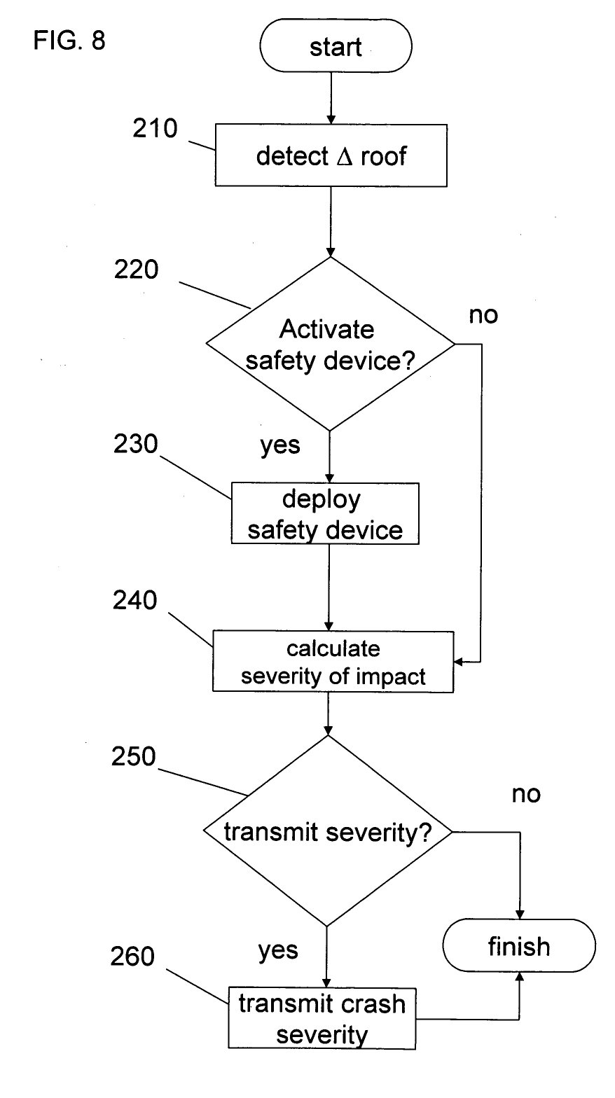

FIG. 8 is a flowchart illustrating the operation of the vehicle safety system 100, according to one embodiment. First, the change in position (deformation) and/or structure of the roof 3 is detected using the sensor 10 (Step 210). The controller 50 processes the signals acquired by the sensor 10 and based on those signals determines whether a safety device 70 should be activated (Steps 220, 230). For example, if the signals acquired by the sensor 10 indicate that the vehicle 1 is in a severe crash scenario the controller 50 can activate a roof airbag to protect the passengers inside the vehicle 1. As shown in Step 240, the controller can also use the signals acquired by the sensor 10 to determine how severe an accident/crash a vehicle has endured by determining the severity of impact on the roof 3 (Step 250). If the crash is deemed severe, the communication device 60 can send a signal indicating a severe crash (Step 260). For example, the communication device 60 may be an automated wireless transmitter that can transmit a distress call to emergency services. If the crash is severe, the passengers may be incapacitated. Thus, the communication device 60 allows the vehicle 1 to call for assistance without relying on the passengers.

The above described sensor and system have several advantages. The sensor can determine whether the severity of a roof deformation caused by impact warrants the deployment of vehicle safety devices such as roof airbags. Further, based on the severity of the roof deformation, the above-described system can transmit information about the vehicle to third parties such as emergency personnel.

The foregoing description of a preferred embodiment of the invention has been presented for purposes of illustration and description. It is not intended to be exhaustive or to limit the invention to the precise form disclosed, and modifications and variations are possible in light of the above teaching or may be acquired from practice of the invention. The embodiment was chosen and described in order to explain the principles of the invention and as a practical application to enable one skilled in the art to utilize the invention in various embodiments and with various modification are suited to the particular use contemplated. It is intended that the scope of the invention be defined by the claims appended hereto and their equivalents.

What is claimed is:

1. A roof sensor system for a vehicle comprising:
a sensor, mounted in proximity to the roof of the vehicle, for monitoring the position of the roof.

2. A roof sensor system as claimed in claim 1, wherein the sensor is a coil.

3. A roof sensor system as claimed in claim 1, further comprising:
a reinforcement member attached to the roof, wherein the sensor is mounted to the reinforcement member.

4. A roof sensor system as claimed in claim 1, further comprising:
a pillar attached to the roof; and
a bracket attached to the pillar, wherein the sensor is attached to the bracket.

5. A roof sensor system as claimed in claim 1, further comprising:
a pillar attached to the roof; and
a bracket attached to the pillar, wherein the sensor is attached to the roof.

6. A roof sensor system as claimed in claim 1, wherein the sensor is any one of an accelerometer, pressure sensor, body sound sensor or magnetostrictive sensor.

7. A roof sensor system as claimed in claim 2, wherein an impedance of the coil changes as the coil approaches metal.

8. A roof sensor system as claimed in claim 2, wherein the coil is an air coil.

9. A roof impact sensor system, comprising:
a coil, mounted in proximity to the roof of the vehicle, for monitoring the position of the roof.

10. A roof impact sensor system as claimed in claim 9, further comprising:
a pillar attached to the roof; and
a bracket attached to the pillar, wherein the coil is attached to the roof.

11. A vehicle safety system, comprising:
a sensor, mounted in proximity to the roof of a vehicle, for monitoring the position of the roof;
a controller, operably connected to the sensor;
a safety device, connected to the controller; and
a vehicle communication device, connected to the controller for communicating a status of the vehicle to a third party.

12. A vehicle safety system as claimed in claim 11, wherein the sensor is a coil.

13. A vehicle safety system as claimed in claim 11, further comprising:
a pillar attached to the roof; and
a bracket attached to the pillar, wherein the coil is attached to the roof.

14. A vehicle safety system as claimed in claim 11, wherein the sensor is any one of an accelerometer, pressure sensor, body sound sensor or magnetostrictive sensor.

15. A vehicle, comprising:
a vehicle safety system, comprising:
a sensor; mounted in proximity to the roof of a vehicle, for monitoring the position of the roof;
a controller, operably connected to the sensor;
a safety device, connected to the controller; and
a vehicle communication device, connected to the controller for communicating a status of the vehicle to a third party.

16. A vehicle, as claimed in claim 15, wherein the sensor is a coil.

17. A vehicle, as claimed in claim 15, further comprising:
a pillar attached to the roof; and
a bracket attached to the pillar, wherein the sensor is attached to the roof.

18. A vehicle safety system as claimed in claim 15, wherein the sensor is any one of an accelerometer, pressure sensor, body sound sensor or magnetostrictive sensor.

19. A method for determining the severity of a roof impact in a vehicle, comprising:
providing a roof sensor;
detecting a change of position of the roof;
determining whether to activate a safety device based on the change of position of the roof; and
calculating the severity of impact on the roof based on the change of position of the roof.

20. A method for determining the severity of a roof impact in a vehicle, further comprising communicating the severity of impact to a third party.
